(19) United States
(12) Patent Application Publication
(10) Pub. No.: US 2025/0185521 A1
(43) Pub. Date: Jun. 5, 2025

(54) ELECTRONIC DEVICE AND METHOD FOR MANUFACTURING ELECTRONIC DEVICE

(71) Applicant: Fujitsu Limited, Kawasaki-shi (JP)

(72) Inventor: Manabu OHTOMO, Kawasaki (JP)

(73) Assignee: Fujitsu Limited, Kawasaki-shi (JP)

(21) Appl. No.: 19/045,596

(22) Filed: Feb. 5, 2025

Related U.S. Application Data
(63) Continuation of application No. PCT/JP2022/032865, filed on Aug. 31, 2022.

(51) Int. Cl. H10N 60/85; H10N 60/01; H10N 60/12

(52) U.S. Cl. CPC H10N 60/85; H10N 60/01; H10N 60/12

(57) ABSTRACT

An electronic device includes a superconducting electrode configured to contain PdTe2 or PdTe and a transition metal dichalcogenide film laminated on the superconducting electrode.

### CROSS-REFERENCE TO RELATED APPLICATION

This application is a continuation application of International Application PCT/JP2022/032865 filed on Aug. 31, 2022 and designated the U.S., the entire contents of which are incorporated herein by reference.

### FIELD

The disclosed technology discussed herein is related to an electronic device and a method for manufacturing the electronic device.

### BACKGROUND

As an electronic device containing transition metal dichalcogenide, the following has been known. For example, a photoelectric device has been known that includes a light receiving unit including a transition metal dichalcogenide layer and a charge induction layer, the charge induction layer covering the transition metal dichalcogenide layer, and a detection unit that includes a topological insulator layer arranged to be away from the transition metal dichalcogenide layer.

U.S. Patent Application Publication No. 2018/0122583 is disclosed as related art.

### SUMMARY

According to an aspect of the embodiments, an electronic device includes a superconducting electrode configured to contain PdTe2 or PdTe and a transition metal dichalcogenide film laminated on the superconducting electrode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating an example of a configuration of an electronic device according to an embodiment of the disclosed technology;

FIG. 2A is a cross-sectional view illustrating an example of a method for manufacturing the electronic device according to the embodiment of the disclosed technology;

FIG. 2B is a cross-sectional view illustrating an example of the method for manufacturing the electronic device according to the embodiment of the disclosed technology;

FIG. 2C is a cross-sectional view illustrating an example of the method for manufacturing the electronic device according to the embodiment of the disclosed technology;

FIG. 2D is a cross-sectional view illustrating an example of the method for manufacturing the electronic device according to the embodiment of the disclosed technology;

FIG. 2E is a cross-sectional view illustrating an example of the method for manufacturing the electronic device according to the embodiment of the disclosed technology;

FIG. 2F is a cross-sectional view illustrating an example of the method for manufacturing the electronic device according to the embodiment of the disclosed technology;

FIG. 2G is a cross-sectional view illustrating an example of the method for manufacturing the electronic device according to the embodiment of the disclosed technology;

FIG. 2H is a cross-sectional view illustrating an example of the method for manufacturing the electronic device according to the embodiment of the disclosed technology;

FIG. 3A is a view illustrating an example of a method for obtaining a peeled piece of a WTe₂ single crystal according to the embodiment of the disclosed technology;

FIG. 3B is a view illustrating an example of the method for obtaining the peeled piece of the WTe₂ single crystal according to the embodiment of the disclosed technology;

FIG. 3C is a view illustrating an example of the method for obtaining the peeled piece of the WTe₂ single crystal according to the embodiment of the disclosed technology;

FIG. 3D is a view illustrating an example of the method for obtaining the peeled piece of the WTe₂ single crystal according to the embodiment of the disclosed technology;

FIG. 3E is a view illustrating an example of the method for obtaining the peeled piece of the WTe₂ single crystal according to the embodiment of the disclosed technology;

FIG. 4 is a view illustrating a state where a superconductor is formed in the vicinity of an interface between Pd and a WTe₂ film;

FIG. 5A is a cross-sectional view illustrating an example of a method for manufacturing an electronic device using an MBE method or a PLD method according to the embodiment of the disclosed technology;

FIG. 5B is a cross-sectional view illustrating an example of the method for manufacturing the electronic device using the MBE method or the PLD method according to the embodiment of the disclosed technology;

FIG. 5C is a cross-sectional view illustrating an example of the method for manufacturing the electronic device using the MBE method or the PLD method according to the embodiment of the disclosed technology;

FIG. 6 is a cross-sectional view illustrating an example of a configuration of an electronic device according to another embodiment of the disclosed technology;

FIG. 7A is a cross-sectional view illustrating an example of a method for manufacturing the electronic device according to the another embodiment of the disclosed technology;

FIG. 7B is a cross-sectional view illustrating an example of the method for manufacturing the electronic device according to the another embodiment of the disclosed technology;

FIG. 7C is a cross-sectional view illustrating an example of the method for manufacturing the electronic device according to the another embodiment of the disclosed technology;

FIG. 7D is a cross-sectional view illustrating an example of the method for manufacturing the electronic device according to the another embodiment of the disclosed technology;

FIG. 7E is a cross-sectional view illustrating an example of the method for manufacturing the electronic device according to the another embodiment of the disclosed technology;

FIG. 7F is a cross-sectional view illustrating an example of the method for manufacturing the electronic device according to the another embodiment of the disclosed technology;

FIG. 8A is a cross-sectional view illustrating an example of a method for partially thinning a WTe₂ film by etching using an ALE method according to the another embodiment of the disclosed technology;

FIG. 8B is a cross-sectional view illustrating an example of the method for partially thinning the WTe₂ film by etching using the ALE method according to the another embodiment of the disclosed technology;

FIG. 8C is a cross-sectional view illustrating an example of the method for partially thinning the WTe₂ film by etching using the ALE method according to the another embodiment of the disclosed technology;

FIG. 8D is a cross-sectional view illustrating an example of the method for partially thinning the WTe₂ film by etching using the ALE method according to the another embodiment of the disclosed technology;

FIG. 9A is a cross-sectional view illustrating an example of a manufacturing method in a case where a superconducting electrode is formed using a Pd/Te alternately stacked film;

FIG. 9B is a cross-sectional view illustrating an example of the manufacturing method in a case where the superconducting electrode is formed using the Pd/Te alternately stacked film;

FIG. 9C is a cross-sectional view illustrating an example of the manufacturing method in a case where the superconducting electrode is formed using the Pd/Te alternately stacked film;

FIG. 9D is a cross-sectional view illustrating an example of the manufacturing method in a case where the superconducting electrode is formed using the Pd/Te alternately stacked film;

FIG. 10 is a plan view illustrating an example of a configuration of an electronic device according to still another embodiment of the disclosed technology; and

FIG. 11 is a plan view illustrating an example of a configuration of an electronic device according to yet another embodiment of the disclosed technology.

### DESCRIPTION OF EMBODIMENTS

In quantum computing, for example, while research on useful algorithms has been progressed in fields of quantum chemical calculation, machine learning, and financial engineering, research on hardware including the Transmon method is developing. With a current small number of physical bits and high error rate, it is not possible to prepare even one useful logical bit.

On the other hand, in the field of physics, presence of a special elementary particle called a Majorana particle has been predicted. A transformation factor of this particle is a 2×2 unitary matrix, and replacement of physical positions of the particles itself is unitary transformation, for example, quantum operation. A quantum computer using the Majorana particles has a system using the fact that sign change of a wave function when the Majorana particle is replaced is the same as that of a quantum gate operation. Whereas a typical quantum computer is rather analog, a qubit using the Majorana particle holds information by a relative positional relationship of the particles, and replacement of the particle position corresponds to the quantum gate operation. Therefore, it can be said that the qubit using the Majorana particles is digital. Since the Majorana particle is derived from a geometric nature of a substance, the Majorana particle is highly resistant to noise that does not impair topology (geometric feature amount).

A problem of the quantum computer using the Majorana particles is that no qubit has been realized yet. As a substance in which the Majorana particle may exist, a topological superconductor that has a low-dimensional structure of a special superconductor has attracted attention. However, suitable candidate substance as the topological superconductor has not been found yet. Therefore, research of an idea such that the topological insulator is brought into contact with a superconductor and superconductivity is induced in the topological insulator by a proximity effect has been conducted.

A problem in development of a Majorana qubit by bonding the topological insulator and the superconductor is stability of the topological insulator. A topological insulator such as WTe2 which is a kind of the transition metal dichalcogenide has a disadvantage that the topological insulator is easily oxidized. Furthermore, many superconductors are easily oxidized. For example, Al and Nb known as a superconductor generates a passive oxide layer on its surface. If an oxide film exists at a bonding interface between the topological insulator and the superconductor, this adversely affects development of the Majorana particles, including not only weakening the proximity effect but also slowing a superconductor gap, for example. For example, the presence of the oxide film on the bonding interface between the topological insulator and the superconductor causes a level in the superconductor gap, weakens protection of the Majorana particle by a topological nature of a substance, and as a result, shortens a lifetime of the Majorana particle. The above problem is a problem that not only the Majorana qubit but also many electronic devices using the transition metal dichalcogenide face.

An object of the disclosed technology is to inhibit formation of an oxide film on an interface between transition metal dichalcogenide and a superconductor.

An example of embodiments of the disclosed technology will be described below with reference to the drawings. Note that, in each drawing, the same or equivalent components and portions will be denoted with the same reference signs, and redundant explanation will be omitted.

### First Embodiment

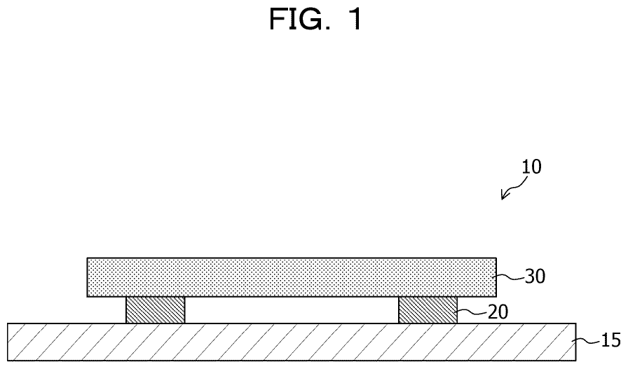

FIG. 1 is a cross-sectional view illustrating an example of a configuration of an electronic device 10 according to a first embodiment of the disclosed technology. The electronic device 10 includes a superconducting electrode 20 that contains PdTe₂ or PdTe and a Transition Metal Dichalcogenide (TMD) film 30 that contains transition metal dichalcogenide laminated on the superconducting electrode 20. The electronic device 10 may be provided on a substrate 15. Although a material of the substrate 15 is not particularly limited, for example, SiO₂ can be used.

The transition metal dichalcogenide forming the TMD film 30 may be a topological insulator. The topological insulator is an insulator that does not exhibit conductivity therein, and a surface is a substance having a metallic property that exhibits the conductivity. The topological insulator may be, for example, WTe₂. As the transition metal dichalcogenide forming the TMD film 30, for example, WSe₂, WS₂, MoSe₂, and MoS₂ can be used. The TMD film 30 may include a single-layer or multi-layer atomic layer material. The electronic device 10 is a bottom-contact type device in which the TMD film 30 covers the superconducting electrode 20.

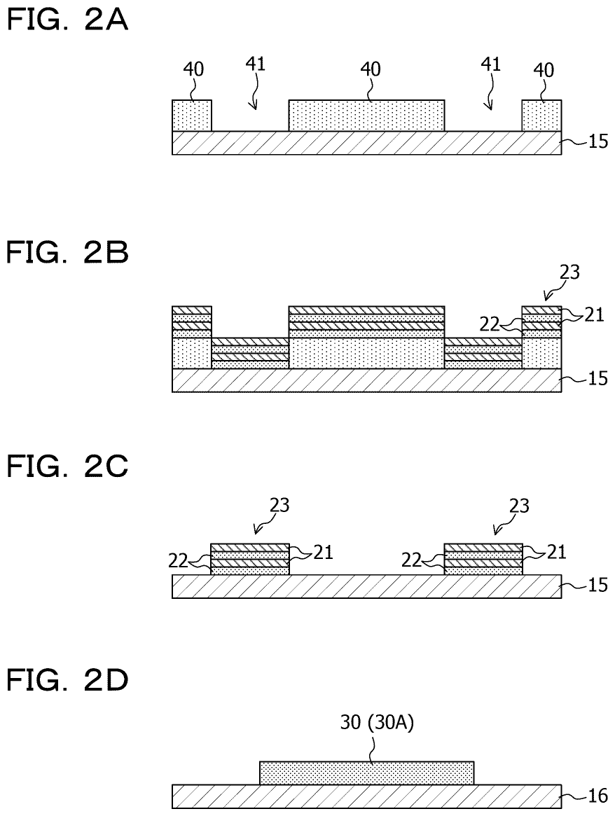

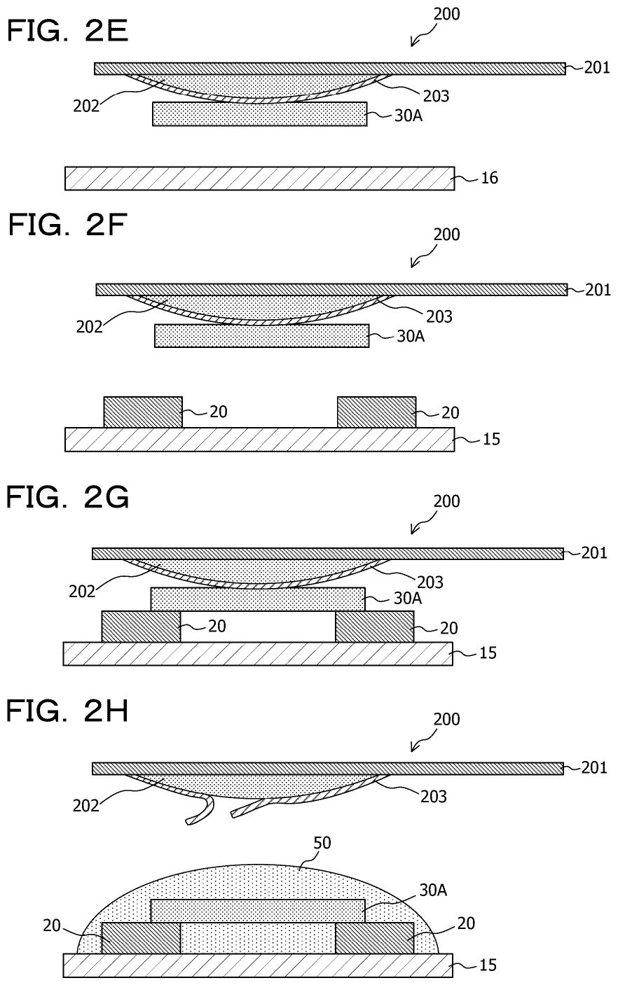

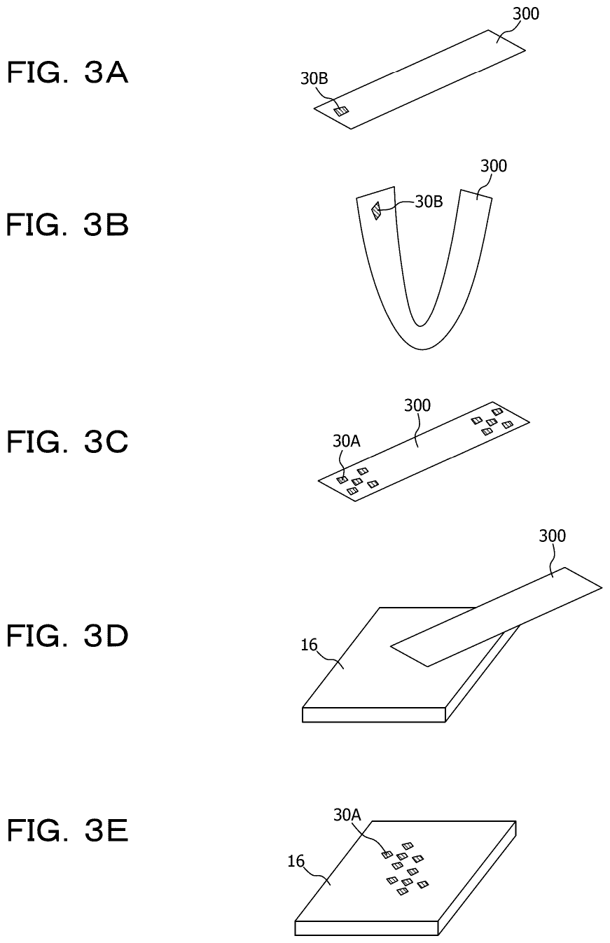

Hereinafter, a method for manufacturing the electronic device 10 will be described. FIGS. 2A to 2H are cross-sectional views illustrating an example of the method for manufacturing the electronic device 10.

First, a resist mask 40 having an opening 41 corresponding to a pattern of the superconducting electrode 20 is formed on the substrate 15 (FIG. 2A). Next, a Pd/Te alternately stacked film 23 is formed by alternately depositing a Pd film 21 and a Te film 22 on the substrate 15 via the resist mask 40 (FIG. 2B). The Pd/Te alternately stacked film 23 can be formed by alternately vapor-depositing each of Pd and Te having a thickness of about several nm (about 10 nm at the maximum), for example, using a binary vapor deposition machine. Furthermore, it is possible to form the Pd/Te alternately stacked film 23 by co-evaporation of Pd and Te. Furthermore, it is possible to form the Pd/Te alternately stacked film 23 by vapor-deposition or sputtering using a mixed target obtained by sintering Pd and Te. In order to minimize surface oxidation, an uppermost layer of the Pd/Te alternately stacked film 23 is preferably the Pd film 21. As a result, it is possible to inhibit oxidation of the Pd/Te alternately stacked film 23. After the formation of the Pd/Te alternately stacked film 23, the Pd/Te alternately stacked film 23 can be exposed to atmosphere or brought into contact with an organic solvent or an organic alkaline developer.

Next, the excess Pd/Te alternately stacked film 23 deposited on the resist mask 40 is removed together with the resist mask 40. For example, the Pd/Te alternately stacked film 23 is patterned by lift-off (FIG. 2C).

Next, the TMD film 30 is formed on a substrate 16 different from the substrate 15 where the Pd/Te alternately stacked film 23 is formed (FIG. 2D). Hereinafter, a case will be described, as an example, where the TMD film 30 is a WTe₂ film 30A. However, the following method is applicable to a case where the TMD film 30 includes transition metal dichalcogenide other than WTe₂.

For example, by transferring a peeled piece of a WTe₂ single crystal on the substrate 16, a single atomic layer or several atomic layers of the WTe₂ film 30A can be formed on the substrate 16. FIGS. 3A to 3E are views illustrating an example of a method for obtaining the peeled piece of the WTe₂ single crystal. The WTe₂ single crystal is obtained by putting tungsten oxide (WO₃) and powdered Te into a quartz glass crucible and heating them. A thickness of the WTe₂ single crystal is about one to two μm. An obtained WTe₂ single crystal 30B is attached to an end of an adhesive surface of an adhesive tape 300 (FIG. 3A).

Next, processing for peeling off, after the end of the adhesive tape 300 to which the WTe₂ single crystal 30B is attached is bonded to an end on an opposite side, is repeatedly executed (FIG. 3B). As a result, the WTe₂ film 30A that is a plurality of peeled pieces of the WTe₂ single crystal 30B can be obtained on the adhesive surface of the adhesive tape 300 (FIG. 3C). Next, a portion of the adhesive tape 300, to which the WTe₂ film 30A is attached, is attached to the substrate 16, and the substrate 16 is heated to a temperature of about 60° C. (FIG. 3D). Thereafter, the adhesive tape 300 is peeled off from the substrate 16. As a result, the WTe₂ film 30A is transferred on the substrate 16 (FIG. 3E).

Next, the WTe₂ film 30A is picked up from the substrate 16 using a transfer jig 200 (FIG. 2E). The transfer jig 200 includes a dome-shaped first resin layer 202 provided on a base 201 and a second resin layer 203 that covers the first resin layer 202. As a material of the base 201, for example, glass can be used. The first resin layer 202 includes a resin having a relatively high temperature at which softening starts. As a material of the first resin layer 202, for example, polydimethylsiloxane (PDMS) can be used. The second resin layer 203 includes a resin having a relatively low softening temperature. As a material of the second resin layer 203, polystyrene (PS) or polypropylene carbonate (PPC), of which a softening start temperature is around 80° C., can be used. When picking up the WTe₂ film 30A using the transfer jig 200, the transfer jig 200 is heated at about 80° C. As a result, the second resin layer 203 is softened and has viscosity. The WTe₂ film 30A is adhered to the second resin layer 203 and is peeled off from the substrate 16.

Next, the WTe₂ film 30A picked up using the transfer jig 200 is laminated on the superconducting electrode 20 (FIGS. 2F and 2G). A process for forming the WTe₂ film 30A on the substrate 16 (FIG. 2D), a process for picking up the WTe₂ film 30A from the substrate 16 (FIG. 2E), and a process for laminating the WTe₂ film 30A on the superconducting electrode 20 (FIGS. 2F and 2G) are performed in a glove box replaced with inert gas. As a result, it is possible to inhibit oxidation of the WTe₂ film 30A.

The superconducting electrode 20 is formed by executing annealing processing at about 180° C. on the Pd/Te alternately stacked film 23 (FIG. 2C) and causing a solid-state reaction in the Pd film 21 and the Te film 22. The superconducting electrode 20 containing PdTe₂ or PdTe is formed by the solid-state reaction of the Pd/Te alternately stacked film 23 (FIG. 2F). The annealing processing is executed in the glove box, before the WTe₂ film 30A is laminated on the superconducting electrode 20. The superconducting electrode 20 and the WTe₂ film 30A are bonded with an intermolecular force.

Next, the transfer jig 200 is heated at about 100° C. to soften the second resin layer 203. As a result, the WTe₂ film 30A is separated from the transfer jig 200. By setting a heating temperature to about 100° C., it is possible to avoid diffusion of Pd included in the superconducting electrode 20 into the WTe₂ film 30A, and characteristics of the WTe₂ film 30A as the topological insulator are maintained. Note that a temperature at which Pd diffuses is equal to or higher than 150° C. A part of the resin forming the second resin layer 203 remains on the side of the WTe₂ film 30A. This residue 50 functions as a protection film that prevents the oxidation of the WTe₂ film 30A and the superconducting electrode 20 (FIG. 2H). Note that the residue 50 may be removed using an organic solvent such as chloroform.

As described above, the electronic device 10 according to the embodiment of the disclosed technology includes the superconducting electrode 20 containing PdTe₂ or PdTe and the TMD film 30 containing the transition metal dichalcogenide laminated on the superconducting electrode 20. The method for manufacturing the electronic device 10 according to the embodiment of the disclosed technology includes a process for forming the superconducting electrode 20 containing PdTe₂ or PdTe, by executing the annealing processing on the film (Pd/Te alternately stacked film 23) containing Pd and Te and causing the solid-state reaction, in an inert gas atmosphere. The method for manufacturing the electronic device 10 includes a process for laminating the TMD film 30 containing the transition metal dichalcogenide and the superconducting electrode 20, in the inert gas atmosphere.

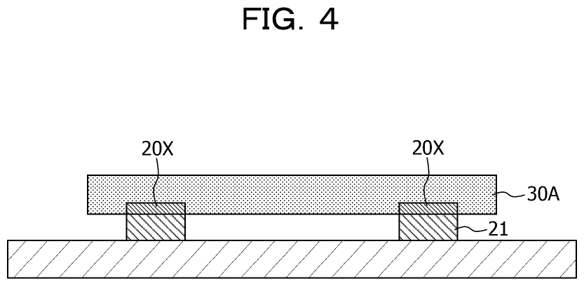

The present inventor has focused on the solid-state reaction between WTe₂ and Pd, in order to realize a structure in which the topological insulator is brought into contact with the superconductor. Although it has been known that superconductivity is developed by bonding WTe₂ and Pd, a mechanism has not been clarified. According to the studies of the present inventor, as illustrated in FIG. 4, it has been clear that Pd diffuses in WTe₂ to cause the solid-state reaction by laminating the WTe₂ film 30A on the Pd film 21 and executing the annealing processing at about 180° C., and a superconductor 20X containing PdTe or PdTe₂ is formed in the vicinity of the interface between the Pd film 21 and the WTe₂ film 30A. In this way, it is possible to obtain the structure in which the topological insulator (WTe₂) and the superconductor (PdTe or PdTe₂) have contact with each other. However, according to this method, when the superconductor 20X is formed on the WTe₂ film 30A, the characteristics of the WTe₂ film 30A as the topological insulator are impaired, due to the diffusion of Pd into the interface between the WTe₂ film 30A and the Pd film 21.

According to the electronic device 10 and the manufacturing method thereof according to the embodiment of the disclosed technology, Te included in the superconducting electrode 20 containing PdTe or PdTe₂ is supplied from the Pd/Te alternately stacked film 23. As a result, it is possible to inhibit to draw Te from the TMD film to the Pd film. For example, it is possible to realize the structure in which the topological insulator and the superconductor have contact with each other, without impairing the characteristics of the TMD film 30 as the topological insulator.

Furthermore, by setting the outermost surface of the Pd/Te alternately stacked film 23 as Pd, it is possible to inhibit the oxidation of the Pd/Te alternately stacked film 23. Furthermore, the process for forming the WTe₂ film 30A on the substrate 16 (FIG. 2D), the process for picking up the WTe₂ film 30A from the substrate 16 (FIG. 2E), and the process for laminating the WTe₂ film 30A on the superconducting electrode 20 (FIGS. 2F and 2G) are performed in the glove box replaced with inert gas. As a result, it is possible to inhibit the oxidation of the WTe₂ film 30A. For example, according to the method for manufacturing the electronic device 10 according to the present embodiment, it is possible to inhibit the formation of the oxide film on the interface between the TMD film 30 and the superconducting electrode 20.

In the above description, a case has been described where the WTe₂ film 30A (TMD film 30) is laminated on the superconducting electrode 20 by transferring the peeled piece of the WTe₂ single crystal. However, the disclosed technology is not limited to this mode. For example, the WTe₂ film 30A (TMD film) can be laminated on the superconducting electrode 20 using a Molecular Beam Epitxy (MBE) method or a Pulsed Laser Deposition (PLD) method. The MBE method is one of physical vapor deposition methods, and is a method for heating a raw material with an electron beam in vacuum and makes a generated molecular beam reach a substrate to perform crystal growth. The PLD method is a method for irradiating a target with a pulsed laser having a high power density in vacuum, ablating and evaporating a target component, and forming a thin film.

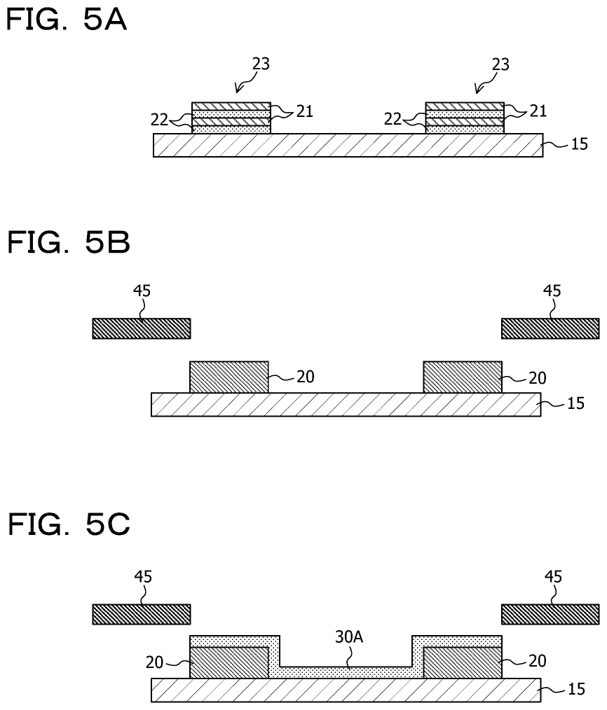

FIGS. 5A to 5C are cross-sectional views illustrating an example of a method for manufacturing the electronic device 10 using the MBE method or the PLD method. The substrate 15 where the Pd/Te alternately stacked film 23 is formed is accommodated in a vacuum chamber of an MBE device or a PLD device (FIG. 5A). Next, by executing the annealing processing at about 180° C. on the Pd/Te alternately stacked film 23 and causing the solid-state reaction in the vacuum chamber, the superconducting electrode 20 containing PdTe₂ or PdTe is formed. Thereafter, a mask 45 having an opening according to a pattern of the WTe₂ film 30A is installed in the vacuum chamber (FIG. 5B). Next, the WTe₂ film 30A is formed on the superconducting electrode 20 using the MBE method or the PLD method (FIG. 5C). A protection film (not illustrated) covering the superconducting electrode 20 and the WTe₂ film 30A may be formed, as necessary.

### Second Embodiment

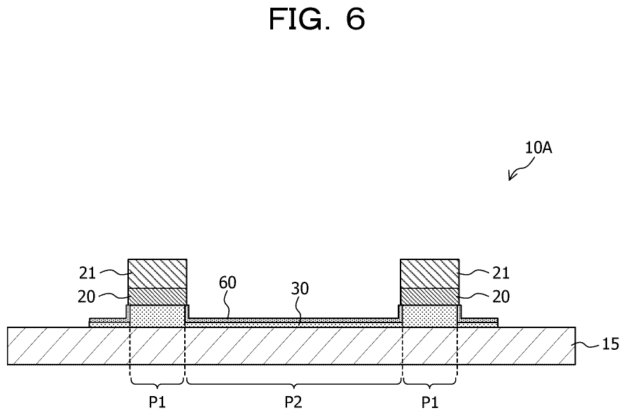

FIG. 6 is a cross-sectional view illustrating an example of a configuration of an electronic device 10A according to a second embodiment of the disclosed technology. The electronic device 10A according to the present embodiment is a top-contact type device in which a superconducting electrode 20 is provided on a TMD film 30. A point that the superconducting electrode 20 contains PdTe₂ or PdTe and the TMD film 30 contains transition metal dichalcogenide is similar to the electronic device 10 according to the first embodiment. The transition metal dichalcogenide may be a topological insulator and may be, for example, WTe₂. The transition metal dichalcogenide forming the TMD film 30 may be, for example, WSe₂, WS₂, MoSe₂, and MoS₂.

The TMD film 30 has a thickness of a first portion P1 that is a portion having contact with the superconducting electrode 20 thicker than a thickness of a second portion P2 that is a portion other than the first portion. The thickness of the second portion P2 of the TMD film 30 is, for example, a thickness of two to four atomic layers. A surface of the TMD film 30 is exposed in the atmosphere and oxidized, and is covered with an oxide film 60. In the second portion P2 of the TMD film 30, only a surface layer of the two to four atomic layers is oxidized. By setting the thickness of the second portion P2 of the TMD film 30 as the thickness of the two to four atomic layers, at least one layer including the lowermost layer is maintained to be in an unoxidized state. A surface of the superconducting electrode 20 may be covered with a Pd film 21.

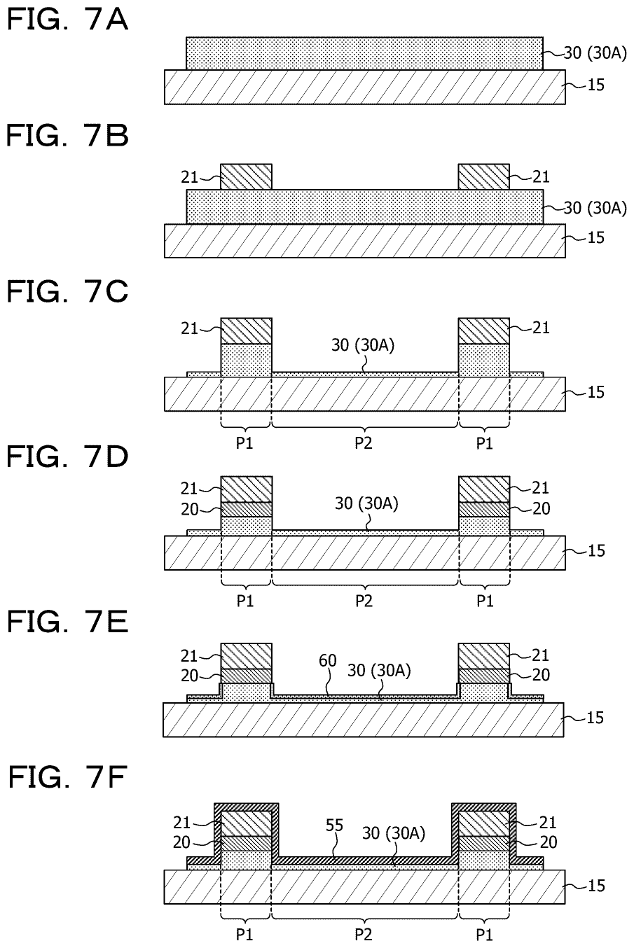

Hereinafter, a method for manufacturing the electronic device 10A will be described. FIGS. 7A to 7F are cross-sectional views illustrating an example of the method for manufacturing the electronic device 10A.

First, a multilayer TMD film 30 is formed on a substrate 15. Hereinafter, a case will be described, as an example, where the TMD film 30 is a WTe₂ film 30A. However, the following method is applicable to a case where the TMD film 30 includes transition metal dichalcogenide other than WTe₂. As in the first embodiment, the multilayer WTe₂ film 30A can be formed by transferring a peeled piece of a WTe₂ single crystal, and can be formed by an MBE method or a PLD method (FIG. 7A).

Next, the Pd film 21 is formed on a surface of the WTe₂ film 30A, using a lift-off method. By the lift-off, the Pd film 21 is patterned into a desired shape (FIG. 7B). Next, by etching the WTe₂ film 30A, using the Pd film 21 as a mask, the WTe₂ film 30A is partially thinned (FIG. 7C). The portion (second portion P2) other than the portion (first portion P1) of the WTe₂ film 30A covered with the Pd film 21 is thinned to have the thickness of the two or four atomic layers. As an etching method of the WTe₂ film 30A, argon milling or Atomic Layer Etching (ALE) can be used.

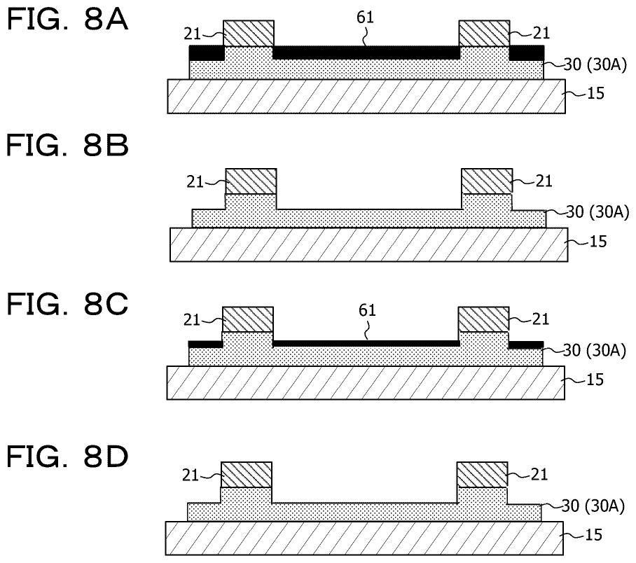

FIGS. 8A to 8D are cross-sectional views illustrating an example of a method for partially thinning the WTe₂ film 30A by etching using the ALE method. First, ultraviolet (UV) ozone processing is executed on the WTe₂ film 30A, using the Pd film 21 as a mask. As a result, a single layer of the outermost surface of the WTe₂ film 30A is oxidized, and an oxide film 61 is formed on the surface of the WTe₂ film 30A (FIG. 8A). Since the WTe₂ film 30A is damaged by irradiation with ultraviolet light, it is preferable to shield the ultraviolet light so that the ultraviolet light is not directly emitted to the WTe₂ film 30A.

Next, the oxide film 61 formed on the surface of the WTe₂ film 30A is removed using a KOH ethanol solution. As a result, the WTe₂ film 30A is thinned by only a thickness of a single atomic layer (FIG. 8B). Here, although it is considered to use a KOH solution to remove the oxide film 61, the WTe₂ film 30A is oxidized by the solution. Since it is necessary to remove the oxide film 61 formed on the surface of the WTe₂ film 30A in an anhydrous environment, it is preferable to use the KOH ethanol solution.

Next, the surface of the WTe₂ film 30A from which the oxide film 61 has been removed is oxidized again by the UV ozone processing, and the oxide film 61 is formed on the surface of the WTe₂ film 30A again (FIG. 8C). Thereafter, the oxide film 61 formed on the surface of the WTe₂ film 30A is removed, using the KOH ethanol solution (FIG. 8D). Processing for forming the oxide film 61 on the surface of the WTe₂ film 30A and processing for removing the oxide film 61 are repeated until the thickness of the portion (second portion P2) other than the portion (first portion P1) covered with the Pd film 21 of the WTe₂ film 30A becomes the thickness of the two to four atomic layers.

After the partial thinning of the WTe₂ film 30A has been completed, annealing processing at about 180° C. is executed on the Pd film 21 and the WTe₂ film 30A. As a result, Pd included in the Pd film 21 is diffused into the WTe₂ film 30A, and the superconducting electrode 20 containing PdTe or PdTe₂ is formed in the vicinity of an interface between the Pd film 21 and the WTe₂ film 30A, by a solid-state reaction. The unreacted Pd film 21 remains on the superconducting electrode 20 (FIG. 7D). Since the WTe₂ film 30A is easily oxidized, there is a possibility that there is an oxide film between the Pd film 21 and the WTe₂ film 30A, at a stage before the annealing processing. However, the Pd film 21 can be diffused into the WTe₂ film 30A through the oxide film existing between the Pd film 21 and the WTe₂ film 30A. On an interface between the superconducting electrode 20 containing PdTe or PdTe₂ formed by the diffusion of the Pd film 21 and the WTe₂ film 30A, no oxide film is formed. Furthermore, a portion of the WTe₂ film 30A immediately below the Pd film 21 may be destroyed by the diffusion of Pd. However, since Pd is not diffused to the thinned portion (second portion P2) of the WTe₂ film 30A, characteristics of the WTe₂ film 30A as a topological insulator are maintained.

Thereafter, an outermost layer of the WTe₂ film 30A is oxidized by exposing the WTe₂ film 30A in the atmosphere, so as to form the oxide film 60. However, at least one layer including the lowermost layer of the WTe₂ film 30A is maintained to be in an unoxidized state (FIG. 7E).

Note that, after the superconducting electrode 20 is formed, before the WTe₂ film 30A is exposed in the atmosphere, a cap film 55 that covers the Pd film 21, the superconducting electrode 20, and the WTe₂ film 30A may be formed (FIG. 7F). The cap film 55 may include, for example, hexagonal boron nitride as a material. By providing the cap film 55, it is possible to inhibit the oxidation of the WTe₂ film 30A. In the configuration including the cap film 55, it is not necessary to assume the oxidation of the WTe₂ film 30A, and the thickness of the portion (second portion P2) other than the portion (first portion P1) covered with the Pd film 21 of the WTe₂ film 30A can be set as a thickness of a single atomic layer.

As described above, the electronic device 10A according to the second embodiment of the disclosed technology is the top-contact type device in which the superconducting electrode 20 is provided on the TMD film 30. In the TMD film 30, the thickness of the first portion P1 that is the portion having contact with the superconducting electrode 20 is thicker than the thickness of the second portion P2 that is the portion other than the first portion P1 of the TMD film 30.

The method for manufacturing the electronic device 10A according to the second embodiment of the disclosed technology includes a process for forming the Pd film 21 on the surface of the multilayer TMD film 30 containing Te and a process for partially thinning the TMD film 30, by etching the TMD film 30 using the Pd film 21 as a mask. The method for manufacturing the electronic device 10A includes a process for forming the superconducting electrode containing PdTe₂ or PdTe in the vicinity of the interface between the Pd film 21 and the TMD film 30, by causing the solid-state reaction by executing the annealing processing on the Pd film 21 and the TMD film 30.

According to the electronic device 10A and the manufacturing method thereof according to the present embodiment, the portion of the WTe₂ film 30A immediately below the Pd film 21 may be destroyed by the diffusion of the Pd film 21. However, since Pd is not diffused to the thinned portion (second portion P2) of the WTe₂ film 30A, the characteristics of the WTe₂ film 30A as the topological insulator are maintained. Furthermore, on the interface between the superconducting electrode 20 containing PdTe or PdTe₂ formed by the diffusion of the Pd film 21 and the WTe₂ film 30A, the oxide film is not formed. For example, according to the method for manufacturing the electronic device 10A according to the present embodiment, it is possible to inhibit the formation of the oxide film on the interface between the TMD film 30 (WTe₂) and the superconducting electrode 20 (PdTe or PdTe₂).

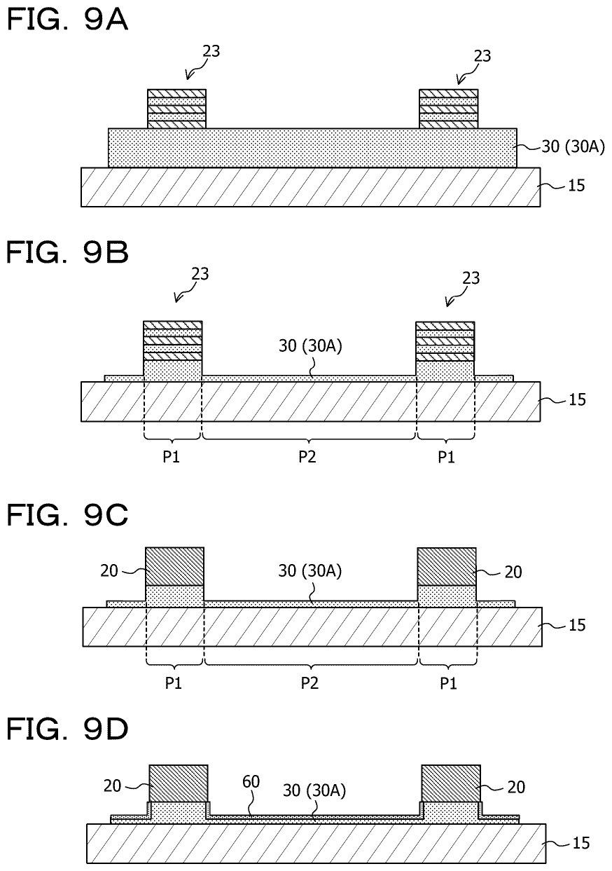

In the above description, a case has been described where the superconducting electrode 20 containing PdTe or PdTe₂ is formed, using the Pd film 21 formed on the surface of the WTe₂ film 30A. However, a Pd/Te alternately stacked film may be used instead of the Pd film 21. FIGS. 9A to 9D are cross-sectional views illustrating an example of a manufacturing method in a case where the superconducting electrode 20 is formed using the Pd/Te alternately stacked film 23.

The Pd/Te alternately stacked film 23 is formed on the surface of the WTe₂ film 30A using the lift-off method. In order to minimize surface oxidation, an uppermost layer of the Pd/Te alternately stacked film 23 is preferably Pd. Furthermore, in order to promote the diffusion of Pd into the WTe₂ film 30A, it is preferable that a lowermost layer of the Pd/Te alternately stacked film 23 be also Pd. By the lift-off, the Pd/Te alternately stacked film 23 is patterned into a desired shape (FIG. 9A).

Next, by etching the WTe₂ film 30A using the Pd/Te alternately stacked film 23 as a mask, the WTe₂ film 30A is partially thinned (FIG. 9B). The portion (second portion P2) other than the portion (first portion P1) of the WTe₂ film 30A covered with the Pd/Te alternately stacked film 23 is thinned to have the thickness of the two to four atomic layers. As the etching method of the WTe₂ film 30A, the argon milling or the Atomic Layer Etching (ALE) can be used.

After the partial thinning of the WTe₂ film 30A has been completed, the annealing processing at about 180° C. is executed on the Pd/Te alternately stacked film 23 and the WTe₂ film 30A. As a result, the solid-state reaction is caused in the Pd/Te alternately stacked film 23, and PdTe or PdTe₂ is formed. Pd is diffused in the WTe₂ film 30A, and PdTe or PdTe₂ is formed in the vicinity of the interface between the Pd/Te alternately stacked film 23 and the WTe₂ film 30A by the solid-state reaction. The superconducting electrode 20 is formed by PdTe or PdTe₂ generated by the solid-state reaction (FIG. 9C). On the interface between the superconducting electrode 20 containing PdTe or PdTe₂ formed by the diffusion of Pd and the WTe₂ film 30A, no oxide film is formed. Furthermore, a portion of the WTe₂ film 30A immediately below the Pd/Te alternately stacked film 23 may be destroyed by the diffusion of Pd. However, since Pd is not diffused to the thinned portion (second portion P2) of the WTe₂ film 30A, characteristics of the WTe₂ film 30A as a topological insulator are maintained.

Thereafter, the outermost layer of the WTe₂ film 30A is oxidized by being exposed in the atmosphere, so as to form the oxide film 60. However, at least one layer including the lowermost layer of the WTe₂ film 30A is maintained to be in an unoxidized state (FIG. 9D).

### Third Embodiment

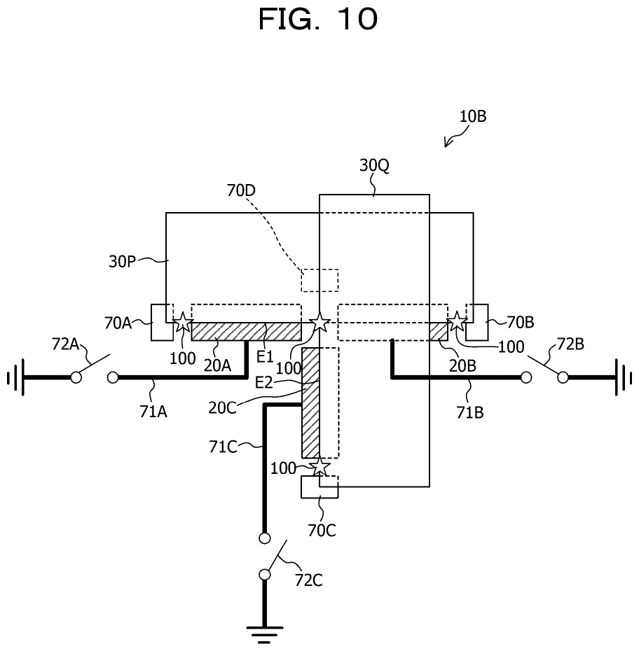

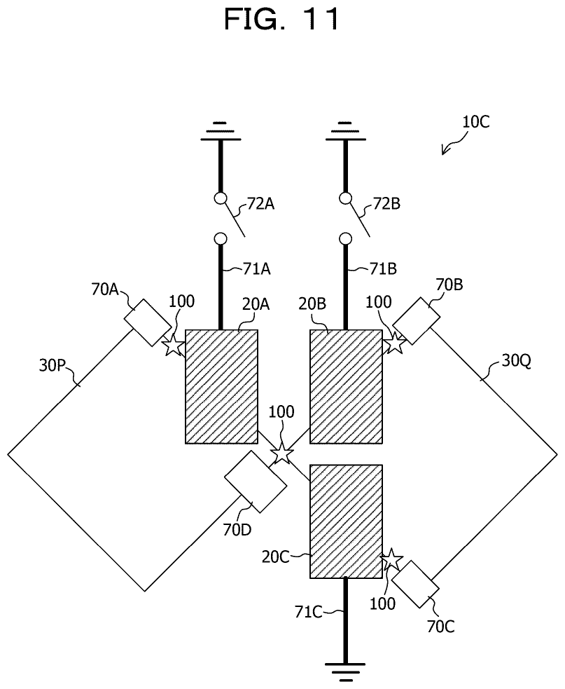

FIG. 10 is a plan view illustrating an example of a configuration of an electronic device 10B according to a third embodiment of the disclosed technology. The electronic device 10B functions as a qubit element using Majorana particles. The electronic device 10B includes a first TMD film 30P, a second TMD film 30Q, superconducting electrodes 20A, 20B, and 20C, and magnetic bodies 70A, 70B, 70C, and 70D. The first TMD film 30P and the second TMD film 30Q include a topological insulator, and may be, for example, single-layer WTe₂ films. The superconducting electrodes 20A to 20C include a superconductor containing PdTe₂ or PdTe.

Each of the first TMD film 30P and the second TMD film 30Q is patterned into a rectangular shape. The first TMD film 30P is arranged such that a longitudinal direction is set as a lateral direction. The second TMD film 30Q is arranged such that a longitudinal direction is set as a vertical direction, and is laminated on the first TMD film 30P while intersecting with the first TMD film 30P. A long side edge E1 of the first TMD film 30P intersects with a long side edge E2 of the second TMD film 30Q.

The superconducting electrodes 20A and 20B are provided in contact with the long side edge E1 of the first TMD film 30P. The superconducting electrode 20C is provided in contact with the long side edge E2 of the second TMD film 30Q. Each of the superconducting electrodes 20A to 20C is patterned into a rectangular shape, and one short side edge thereof is positioned near an intersection between the long side edge E1 of the first TMD film 30P and the long side edge E2 of the second TMD film 30Q. The superconducting electrode 20A is provided in contact with an edge forming a corner having contact with the second TMD film 30Q, of the first TMD film 30P. The electronic device 10B is a bottom-contact type in which the first TMD film 30P and the second TMD film 30Q are laminated on the superconducting electrodes 20A to 20C.

The magnetic body 70A has contact with the long side edge E1 of the first TMD film 30P and is provided near another short side edge of the superconducting electrode 20A. The magnetic body 70B has contact with the long side edge E1 of the first TMD film 30P and is provided near another short side edge of the superconducting electrode 20B. The magnetic body 70C has contact with the long side edge E2 of the second TMD film 30Q and is provided near another short side edge of the superconducting electrode 20C. The magnetic body 70D is provided near the intersection between the long side edge E1 of the first TMD film 30P and the long side edge E2 of the second TMD film 30Q. As the magnetic bodies 70A to 70D, for example, Ni, Co, or Fe can be used.

Superconducting wiring lines 71A, 71B, and 71C are respectively coupled to the superconducting electrodes 20A, 20B, and 20C. Similarly to the superconducting electrodes 20A, 20B, and 20C, each of the superconducting wiring lines 71A, 71B, and 71C may include a superconductor containing PdTe₂ or PdTe. Furthermore, the superconducting wiring lines 71A, 71B, and 71C may have, for example, a two-layer structure in which PdTe₂ and Al are stacked or a two-layer structure in which NbTe₂ and Nb are stacked. Switches 72A, 72B, and 72C are provided respectively on routes of the superconducting wiring lines 71A, 71B, and 71C. The switches 72A, 72B, and 72C may be Josephson junction elements. Each of the switches 72A, 72B, and 72C is coupled to a ground potential.

According to the electronic device 10B of the present embodiment, Majorana particles 100 are generated at each of a position between the superconducting electrode 20A and the magnetic body 70A, at the intersection with the long side edge E2 of the second TMD film 30Q, and between the superconducting electrode 20B and the magnetic body 70B, at the long side edge E1 of the first TMD film 30P. Furthermore, the Majorana particles 100 are generated at a position between the superconducting electrode 20C and the magnetic body 70C, at the long side edge E2 of the second TMD film 30Q. The Majorana particles 100 can be localized by the magnetic bodies 70A to 70D. By turning on/off the switches 72A, 72B, and 72C and causing the superconducting electrodes 20A, 20B, and 20C to be in earth fault or float, the Majorana particles 100 generated at the respective portions can be exchanged.

### Fourth Embodiment

FIG. 11 is a plan view illustrating an example of a configuration of an electronic device 10C according to a fourth embodiment of the disclosed technology. The electronic device 10C functions as a qubit element using Majorana particles. The electronic device 10C includes a first TMD film 30P, a second TMD film 30Q, superconducting electrodes 20A, 20B, and 20C, and magnetic bodies 70A, 70B, 70C, and 70D. The first TMD film 30P and the second TMD film 30Q include a topological insulator, and may be, for example, single-layer WTe₂ films. The superconducting electrodes 20A to 20C include a superconductor containing PdTe₂ or PdTe.

Each of the first TMD film 30P and the second TMD film 30Q is patterned into a rectangle. Note that it is sufficient that the first TMD film 30P and the second TMD film 30Q only need to have at least one corner, and the first TMD film 30P and the second TMD film 30Q may have a polygonal shape other than a quadrangle or other shapes. One corner of the second TMD film 30Q has contact with one corner of the first TMD film 30P. The superconducting electrode 20A is provided in contact with an edge forming a corner having contact with the second TMD film 30Q, of the first TMD film 30P. The superconducting electrode 20B is provided in contact with one edge forming a corner having contact with the first TMD film 30P, of the second TMD film 30Q. The superconducting electrode 20C is provided in contact with another edge forming a corner having contact with the first TMD film 30P, of the second TMD film 30Q. The electronic device 10C is a top-contact type in which the superconducting electrodes 20A to 20C are laminated on the first TMD film 30P and the second TMD film 30Q.

The magnetic body 70A has contact with the edge forming the corner having contact with the second TMD film 30Q, of the first TMD film 30P and is provided near the superconducting electrode 20A. The magnetic body 70B has contact with one edge forming the corner having contact with the first TMD film 30P, of the second TMD film 30Q and is provided near the superconducting electrode 20B. The magnetic body 70C has contact with another edge forming the corner having contact with the first TMD film 30P, of the second TMD film 30Q and is provided near the superconducting electrode 20C. The magnetic body 70D is provided near a corner where the first TMD film 30P and the second TMD film 30Q have contact with each other.

Superconducting wiring lines 71A, 71B, and 71C are respectively coupled to the superconducting electrodes 20A, 20B, and 20C. Similarly to the superconducting electrodes 20A, 20B, and 20C, each of the superconducting wiring lines 71A, 71B, and 71C may include a superconductor containing PdTe₂ or PdTe. Furthermore, the superconducting wiring lines 71A, 71B, and 71C may have, for example, a two-layer structure in which PdTe₂ and Al are stacked or a two-layer structure in which NbTe₂ and Nb are stacked. The switches 72A and 72B are respectively provided on routes of the superconducting wiring lines 71A and 71B. The switches 72A and 72B may be Josephson junction elements. Each of the switches 72A and 72B and the superconducting wiring line 71C is coupled to a ground potential.

According to the electronic device 10C of the present embodiment, the Majorana particles 100 are generated at the position between the superconducting electrode 20A and the magnetic body 70A, at the edge forming the corner, having contact with the second TMD film 30Q, of the first TMD film 30P. Furthermore, the Majorana particles 100 are generated between the superconducting electrode 20B and the magnetic body 70B, at the one edge forming the corner having contact with the first TMD film 30P, of the second TMD film 30Q. Furthermore, the Majorana particles 100 are generated between the superconducting electrode 20C and the magnetic body 70C, at the another edge forming the corner having contact with the first TMD film 30P, of the second TMD film 30Q. Furthermore, the Majorana particles 100 are generated at the corner where the first TMD film 30P and the second TMD film 30Q have contact with each other. The Majorana particles 100 can be localized by the magnetic bodies 70A to 70D. By turning on/off the switches 72A and 72B and causing the superconducting electrodes 20A and 20B to be in earth fault or float, the Majorana particles 100 generated at the respective portions can be exchanged with each other.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a superconducting electrode configured to contain PdTe₂ or PdTe; and
a transition metal dichalcogenide film laminated on the superconducting electrode.

2. The electronic device according to claim 1, wherein
the transition metal dichalcogenide film is a topological insulator film.

3. The electronic device according to claim 2, wherein
the transition metal dichalcogenide film is a WTe₂ film.

4. The electronic device according to claim 1, wherein
the transition metal dichalcogenide film is a film that includes a single-layer or multi-layer atomic layer material.

5. The electronic device according to claim 1, wherein
the transition metal dichalcogenide film has a thickness of a first portion that is a portion that has contact with the superconducting electrode, thicker than a thickness of a second portion that is a portion other than the first portion.

6. The electronic device according to claim 1, wherein
the transition metal dichalcogenide film includes a first transition metal dichalcogenide film and a second transition metal dichalcogenide film that intersects with the first transition metal dichalcogenide film and is laminated on the first transition metal dichalcogenide film, and
a plurality of the superconducting electrodes is provided in contact with edges of the first transition metal dichalcogenide film and the second transition metal dichalcogenide film that intersect with each other.

7. The electronic device according to claim 1, wherein
the transition metal dichalcogenide film includes a first transition metal dichalcogenide film that has at least one corner and a second transition metal dichalcogenide film that has at least one corner and has one corner provided in contact with the one corner of the first transition metal dichalcogenide film, and
a plurality of the superconducting electrodes is provided in contact with an edge that forms a corner that has contact with the second transition metal dichalcogenide film, of the first transition metal dichalcogenide film and an edge that forms a corner that has contact with the first transition metal dichalcogenide film, of the second transition metal dichalcogenide film.

8. The electronic device according to claim 6, further comprising:
a superconducting wiring line coupled to each of the plurality of superconducting electrodes; and
a switch provided on a route of each superconducting wiring line.

9. A method for manufacturing an electronic device comprising:
forming a superconducting electrode that contains PdTe₂ or PdTe; and
laminating a transition metal dichalcogenide film and the superconducting electrode.

10. The method according to claim 9, wherein
the forming the superconducting electrode is executed by forming a Te film and forming a Pd film that has contact with the Te film, and causing a solid-state reaction by executing annealing processing on the Te film and the Pd film.

11. The method according to claim 10, wherein
the annealing processing is executed in vacuum or in an inert gas atmosphere, and
the laminating the transition metal dichalcogenide film and the superconducting electrode is executed in the vacuum or the inert gas atmosphere.

12. A method for manufacturing an electronic device comprising:
forming a Pd film on a surface of a multi-layer transition metal dichalcogenide film that contains Te;
partially thinning the transition metal dichalcogenide film, by etching the transition metal dichalcogenide film by using the Pd film as a mask; and
forming a superconducting electrode that contains PdTe₂ or PdTe on an interface between the Pd film and the transition metal dichalcogenide film, by causing a solid-state reaction by executing annealing processing on the Pd film and the transition metal dichalcogenide film.
